(19) United States
(12) Patent Application Publication
(10) Pub. No.: US 2009/0083958 A1
(43) Pub. Date: Apr. 2, 2009

(54) METHOD OF MANUFACTURING PIEZOELECTRIC ACTUATOR, LIQUID EJECTION HEAD AND IMAGE FORMING APPARATUS

(76) Inventor: Ryuji TSUKAMOTO, Kanagawa-Ken (JP)

Correspondence Address: BIRCH STEWART KOLASCH & BIRCH, PO BOX 747, FALLS CHURCH, VA, 22040-0747, US

(21) Appl. No.: 12/239,576

(22) Filed: Sep. 26, 2008

(30) Foreign Application Priority Data
Sep. 28, 2007 (JP) 2007-256721

(51) Int. Cl. H01L 41/22; B41J 2/045

(52) U.S. Cl. 29/25.35; 347/20

(57) ABSTRACT

A method of manufacturing a piezoelectric actuator including an upper electrode film, a lower electrode film and a piezoelectric film arranged between the upper electrode film and the lower electrode film, the piezoelectric film being made of a material having a perovskite crystal structure as represented by a general formula ABO₃, where A includes at least one of Pb and Ba, and B includes at least one of Zr and Ti, the method includes the steps of: forming the piezoelectric film on the lower electrode film; and then annealing the piezoelectric film in an oxygen atmosphere at a temperature not higher than a temperature having been applied to the piezoelectric film during the step of forming.

### BACKGROUND OF THE INVENTION

1. Field of the Invention

The present invention relates to a method of manufacturing a piezoelectric actuator in which a piezoelectric film is arranged between an upper electrode film and a lower electrode film, and to a liquid ejection head and an image forming apparatus.

2. Description of the Related Art

A piezoelectric actuator having a piezoelectric film arranged between an upper electrode film and a lower electrode film is known and used, for example, in an inkjet recording type of recording head (inkjet head). In general, this piezoelectric actuator has a structure in which a lower electrode film, a piezoelectric film and an upper electrode film are layered in this order onto a diaphragm, which forms one wall of a pressure chamber, and when an electric field is applied to the piezoelectric film, the piezoelectric film expands or contracts in the direction perpendicular to the thickness direction thereof, causing the diaphragm to deform toward the side of the pressure chamber, the ink inside the pressure chamber is thereby pressurized, and consequently an ink droplet is ejected from the nozzle connected to the pressure chamber.

As a method of manufacturing the above-described piezoelectric actuator, a method is known in which a lower electrode film, a piezoelectric film and an upper electrode film are formed successively as thin films by a sputtering method, or the like, and thereby the piezoelectric actuator can be formed of very thin films and the size of the inkjet head can be reduced. For example, there is a method in which a piezoelectric film of a material having the pyrochlore crystal structure is deposited at a low temperature (for example, 300° C.) by sputtering, and this piezoelectric film is then annealed at a higher temperature than the deposition temperature (for example, 650° C.), thereby forming the perovskite crystal structure.

In recent years, one technical issue has been to improve the performance and reliability of the piezoelectric actuators used in inkjet heads, in order to achieve high-resolution and high-quality image recording. More specifically, there have been demands for piezoelectric actuators having high reliability which improve the piezoelectric characteristics of the piezoelectric film which is deposited by sputtering, or the like, as well as preventing the detachment of films.

Japanese Patent Application Publication No. 2001-185774 describes a method for forming a piezoelectric film by repeating, a plurality of times, steps of depositing a film of piezoelectric material onto a substrate on which a centrifugal force is acting in the thickness direction thereof, and carrying out an annealing treatment.

Japanese Patent Application Publication No. 2002-217469 describes a method in which a piezoelectric film of a material having the perovskite structure containing Pb, Zr and Ti is deposited by sputtering, and heat treatment is then carried out at a temperature not lower than the temperature during deposition.

Japanese Patent Application Publication No. 2003-188429 describes a method of forming a piezoelectric layer in which the crystal structure and the preferred-orientation plane are controlled by a sputtering method, or the like, directly after depositing a thin film of piezoelectric material, without carrying out a crystallization process involving heat treatment.

In general, an annealing treatment is carried out in order to improve the crystallinity of a piezoelectric film which has been deposited by a sputtering method or the like, but if the film is simply subjected to annealing, then problems arise in that the detachment of the piezoelectric film occurs, and satisfactory piezoelectric characteristics cannot be obtained.

In a method in which a piezoelectric film of a material having the pyrochlore crystal structure is deposited by a sputtering method and the piezoelectric film is then annealed to form the perovskite crystal structure, it is necessary to anneal the piezoelectric film at a temperature equal to or higher than the temperature during deposition, and problems arise in that detachment of the film becomes liable to occur due to the difference in the coefficient of linear expansion between the piezoelectric film and the substrate on which the piezoelectric film is deposited.

In Japanese Patent Application Publication No. 2001-185774, it is problematic that the step of depositing a piezoelectric material onto a substrate and the step of annealing are repeated inside the same vacuum apparatus, and it is not possible to achieve satisfactory piezoelectric characteristics due to the lack of oxygen in the lattice of the piezoelectric material. Furthermore, due to the repetition of the film deposition and annealing steps, it takes a long time to form the film, and hence there is a problem of low productivity.

In Japanese Patent Application Publication No. 2002-217469, it is problematic that, similarly to the above-described method which deposits a piezoelectric film of a material having the pyrochlore crystal structure by a sputtering method then performs annealing of the piezoelectric film so as to form the perovskite crystal structure, the piezoelectric film is annealed at a temperature equal to or higher than the temperature during film deposition, and therefore detachment of the piezoelectric film is liable to occur.

In Japanese Patent Application Publication No. 2003-188429, it is problematic that heat treatment is not carried out in an oxygen atmosphere and therefore satisfactory piezoelectric characteristics cannot be obtained.

### SUMMARY OF THE INVENTION

The present invention has been contrived in view of these circumstances, an object thereof being to provide a method of manufacturing a piezoelectric actuator, a liquid ejection head and an image forming apparatus, having high reliability, which prevents detachment of the piezoelectric film as well as improving piezoelectric characteristics.

In order to attain the aforementioned object, the present invention is directed to a method of manufacturing a piezoelectric actuator comprising an upper electrode film, a lower electrode film and a piezoelectric film arranged between the upper electrode film and the lower electrode film, the piezoelectric film being made of a material having a perovskite crystal structure as represented by a general formula ABO₃, where A includes at least one of Pb and Ba, and B includes at least one of Zr and Ti, the method comprising the steps of: forming the piezoelectric film on the lower electrode film; and then annealing the piezoelectric film in an oxygen atmosphere at a temperature not higher than a temperature having been applied to the piezoelectric film during the step of forming.

According to the present invention, by annealing the piezoelectric film in the oxygen atmosphere at the temperature equal to or lower than the prescribed heating temperature (film formation temperature), it is possible to prevent detachment of the piezoelectric film, as well as improving the piezoelectric characteristics. Consequently, it is possible to achieve a piezoelectric actuator having high reliability.

It is desirable that the heating temperature during the annealing of the piezoelectric film (the annealing temperature) is equal to or lower than the film formation temperature of the piezoelectric film, since this makes it possible to prevent detachment of the piezoelectric film more reliably. It is more desirable that the annealing temperature is equal to or higher than 100° C., since this makes it possible to obtain an effect in enhancing the piezoelectric characteristics by means of the annealing process.

The method used to form the piezoelectric film having the perovskite crystal structure may be sputtering, sol gelation, chemical vapor deposition, aerosol deposition, or the like.

Preferably, the piezoelectric film is formed by a sputtering method.

According to this aspect of the present invention, sputtering is desirable as the method for forming the piezoelectric film, since this makes it possible to readily form the piezoelectric film having the perovskite crystal structure.

Preferably, an oxygen concentration of the oxygen atmosphere is not lower than 10 vol %.

According to this aspect of the present invention, it is possible further to enhance the piezoelectric characteristics by means of the annealing process.

Preferably, the method further comprises the step of forming the upper electrode film on the piezoelectric film before the step of annealing.

According to this aspect of the present invention, it is possible to improve the piezoelectric characteristics compared to a case where the annealing is carried out after forming the upper electrode film on the piezoelectric film.

In order to attain the aforementioned object, the present invention is also directed to a liquid ejection head, comprising a piezoelectric actuator manufactured by the above-described method.

According to this aspect of the present invention, it is possible to achieve the liquid ejection head having high reliability, as well as excellent ejection characteristics.

In order to attain the aforementioned object, the present invention is also directed to an image forming apparatus, comprising the above-described liquid ejection head.

According to this aspect of the present invention, it is possible to form images of high quality.

According to the present invention, by annealing the piezoelectric film in the oxygen atmosphere at the temperature equal to or lower than the prescribed heating temperature (film formation temperature), it is possible to prevent detachment of the piezoelectric film, as well as improving the piezoelectric characteristics. Consequently, it is possible to achieve the piezoelectric actuator having high reliability.

### BRIEF DESCRIPTION OF THE DRAWINGS

The nature of this invention, as well as other objects and advantages thereof, will be explained in the following with reference to the accompanying drawings, in which like reference characters designate the same or similar parts throughout the figures and wherein:

FIG. 1 is a cross-sectional diagram showing a part of an embodiment of the composition of a recording head;

FIGS. 2A to 2J are step diagrams showing an embodiment of a method of manufacturing a recording head;

FIG. 3 is a graph showing the results of evaluation experiment 1;

FIGS. 4A and 4B are tables showing the detailed data of the graphs shown in FIG. 3;

FIG. 5 is a graph showing the results of evaluation experiment 2;

FIG. 6 is a general schematic drawing showing a general view of an inkjet recording apparatus;

FIG. 7 is a principal plan diagram showing the peripheral area of a printing unit of an inkjet recording apparatus; and

FIG. 8 is a principal block diagram showing the control system of an inkjet recording apparatus.

### DETAILED DESCRIPTION OF THE PREFERRED EMBODIMENTS

Here, the composition of an inkjet head having piezoelectric actuators to which the present invention is applied (hereinafter, called the “recording head”) is described as one embodiment of the liquid ejection head according to the present invention, and thereupon a method of manufacturing this recording head will be described.

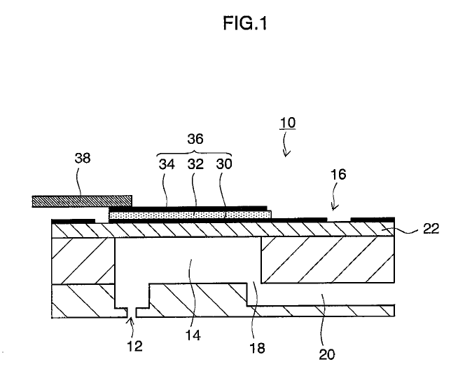

FIG. 1 is a cross-sectional diagram showing the principal composition of a recording head according to the present embodiment. As shown in FIG. 1, the recording head 10 according to the present embodiment principally comprises a nozzle 12, which forms an ink ejection port, a pressure chamber 14, which is connected to the nozzle 12, and a piezoelectric actuator 16, which alters the internal volume of the pressure chamber 14.

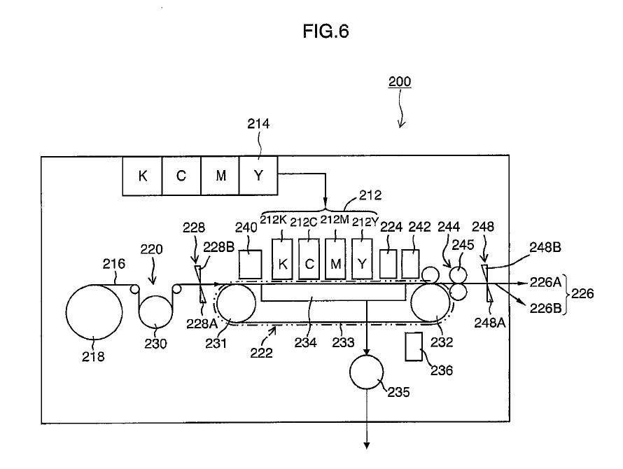

Although not shown in FIG. 1, there are a plurality of the nozzles 12 arranged in a two-dimensional arrangement (matrix configuration) in the ejection face (nozzle surface) of the recording head 10. The pressure chambers 14 corresponding respectively to the nozzles 12 are arranged inside the recording head 10, and each nozzle 12 is connected to the corresponding pressure chamber 14. Ink supply ports 18 are formed respectively at ends of the pressure chambers 14 (the ends on the opposite sides to the sides where the nozzles 12 are connected in FIG. 1). The pressure chambers 14 are connected to a common flow channel 20 through the ink supply ports 18, and the ink inside the common flow channel 20 is thereby distributed and supplied to the pressure chambers 14. Ink is supplied to the common flow channel 20 from an ink tank (not illustrated) which is disposed in an ink storing and loading unit 214 shown in FIG. 6.

The piezoelectric actuator 16 shown in FIG. 1 has a structure in which a lower electrode film 30, a piezoelectric film 32 and an upper electrode film 34 are successively layered at a position corresponding to each pressure chamber 14 on the diaphragm 22, which constitutes a wall of the pressure chamber 14 (the upper surface in FIG. 1). The lower electrode film 30, the piezoelectric film 32 and the upper electrode film 34 corresponding to each pressure chamber 14 constitute a piezoelectric element 36, which functions as a pressure generating device that applies pressure to the ink inside the pressure chamber 14.

The lower electrode films 30 and the upper electrode films 34 are made of an electrode material such as Ir, Pt, Ti, or the like, and are arranged at the positions corresponding to the pressure chambers 14, as described above.

The present embodiment adopts a structure (upper address structure) in which the lower electrode film 30 is a common electrode, and the upper electrode film 34 is an individual electrode, and an external wire (for example, a flexible cable, or the like) 38 is connected to the upper electrode film (individual electrode) 34. On the other hand, the lower electrode films (common electrodes) 30 corresponding to the pressure chambers 14 are electrically connected together at a position which is not shown in the drawing, and they are earthed. In a mode where the lower electrode film 30 is a common electrode, it is possible to form the lower electrode film 30 over the whole surface of the diaphragm 22.

The piezoelectric film 32 is a piezoelectric body made of a metallic oxide that has the perovskite crystal structure (hereinafter, called the “perovskite structure”), which is generally represented by ABO₃, where A includes at least one of Pb and Ba, B includes at least one of Zr and Ti, and O is oxygen. Moreover, B may also include at least one of V, Nb and Ta. More specifically, for example, the piezoelectric body may be made of lead zirconate titanate (Pb (Zr, Ti)O₃), barium titanate (BaTiO₃), or the like. Here, the “perovskite structure” means that the peak of ABO₃ is the first peak in X-ray diffraction (XRD).

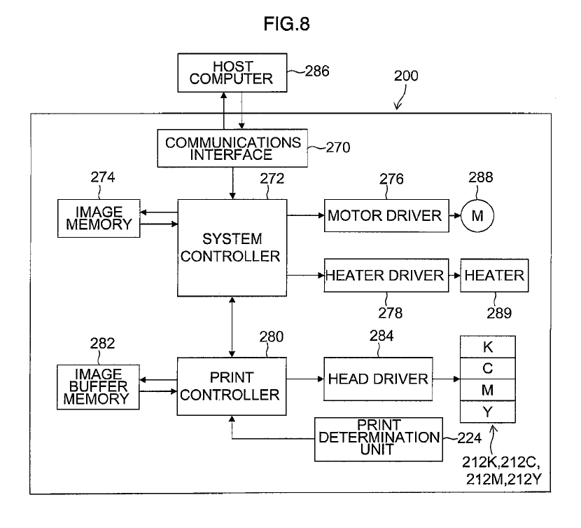

When a prescribed drive signal is supplied to the upper electrode film (individual electrode) 34 of the piezoelectric element 36 from a head driver 284 (not shown in FIG. 1 but shown in FIG. 8) through the external wire 38, thereby an electric field is applied to the piezoelectric film 32 disposed between the lower electrode film 30 and the upper electrode film 34, the diaphragm 22 is deformed so as to project toward the pressure chamber 14 side due to the expansion and contraction of the piezoelectric film 32, and consequently, the ink inside the pressure chamber 14 is pressurized and an ink droplet is ejected from the nozzle 12 connected to the pressure chamber 14. When the diaphragm 22 returns to its original state after the ejection of ink, new ink is supplied to the pressure chamber 14 from the common flow channel 20 through the ink supply port 18, thus preparing for the next ink ejection operation.

Below, a method of manufacturing the piezoelectric actuator according to the present embodiment is described.

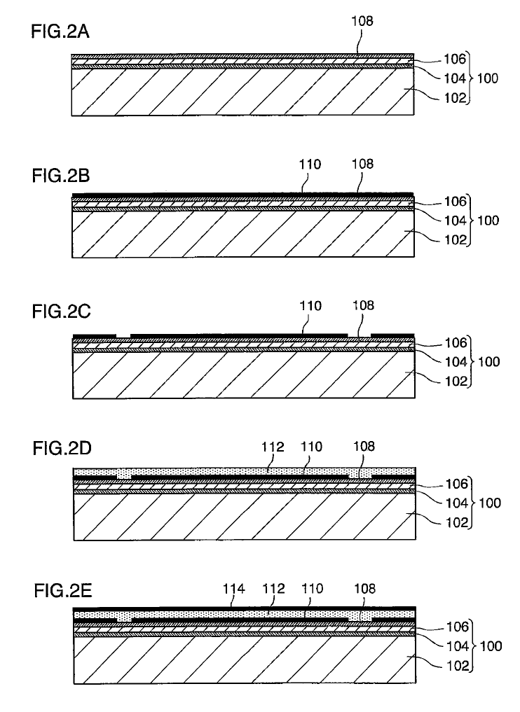

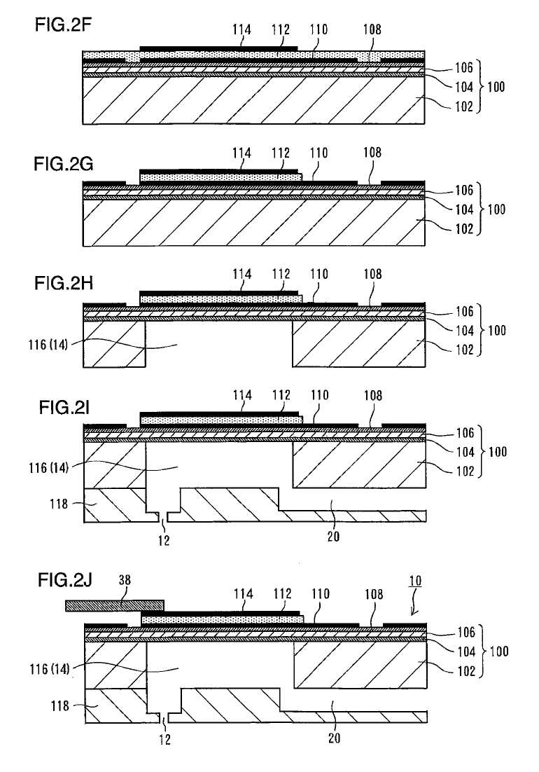

FIGS. 2A to 2J are step diagrams showing an example of a method of manufacturing the recording head 10 according to the present embodiment, and they include the method of manufacturing a piezoelectric actuator according to the present invention.

Firstly, an SOI (silicon on insulator) substrate 100 having an insulating layer 108 formed on the surface thereof is prepared (FIG. 2A). The SOI substrate 100 is a multiple-layer substrate, which has a supporting layer 102 constituted of an Si (silicon) substrate, a box layer 104 constituted of an SiO₂ (silicon oxide) film, and an active layer 106 constituted of an Si substrate. The insulating film 108 is constituted of the SiO₂ film, and it can be formed by an oxidation method, a sputtering method, a CVD (chemical vapor deposition) method, or the like. The insulating layer 108 may be constituted of another oxide, such as ZrO₂, Al₂O₃, or the like, a nitride, such as SiCN, TiAlN, Si₃N₄ or TiAlCrN, an oxynitride, such as SiON, a resin, or the like.

Next, a lower electrode film 110 is formed over the whole surface of the insulating layer 108 (FIG. 2B). Examples of the material of the lower electrode film 110 include electrode material, such as Ir, Pt or Ti. A method such as sputtering, vapor deposition, CVD, or the like, may be used to form the lower electrode film 110. The thickness of the lower electrode film 110 is 100 nm to 300 nm, for example. Subsequently, the lower electrode film 110 is patterned by etching (FIG. 2C). More specifically, the lower electrode film 110 is divided into individual areas for the respective pressure chambers 14 (see FIG. 1) by dry etching (RIE). Instead of the steps of forming the solid lower electrode film 110 over the insulating layer 108 and then etching same, it is also possible to form pieces of lower electrode film 110 at positions corresponding to the respective pressure chambers 14, by means of a lift-off film deposition method which uses a resist.

Next, a piezoelectric film 112 is formed on the upper surface of the SOI substrate 100, so as to cover the lower electrode film 110, which is situated on the insulating layer 108 (FIG. 2D). More specifically, the piezoelectric film 112 constituted of a metal oxide having the perovskite crystal structure represented by the general formula ABO₃ described above is deposited. It is possible to use a method such as sputtering, sol gelation, CVD, aerosol deposition, or the like, as the method of forming the piezoelectric film 112 having the perovskite structure of this kind, and of these methods, a sputtering method is desirable from the viewpoint of the film thickness and piezoelectric characteristics. In the present embodiment, the piezoelectric film 112 of the perovskite structure is deposited by sputtering, the temperature dining the deposition of this piezoelectric film 112 (film forming temperature) is 550° C., and the film thickness of the piezoelectric film 112 is 1 μm to 5 μm, for example.

Next, after depositing the piezoelectric film 112 having the perovskite structure, the piezoelectric film 112 is subjected to an annealing process at a prescribed heating temperature (annealing temperature) in an oxygen atmosphere. The annealing temperature is equal to or lower than the film formation temperature of the piezoelectric film 112. Accordingly, it is possible to prevent detachment of the piezoelectric film 112, as well as being able to improve the piezoelectric characteristics. Furthermore, desirably, the oxygen concentration in the oxygen atmosphere in which the annealing process is carried out is equal to or higher than 10 vol %, and in this case, the piezoelectric characteristics of the piezoelectric film 112 can be enhanced further.

Next, an upper electrode film 114 is formed over the whole surface of the piezoelectric film 112 (FIG. 2E). Examples of the material of the upper electrode film 114 include electrode material, such as Ir, Pt, Ti, or Au. The upper electrode film 114 may be formed by a method such as sputtering, vapor deposition, CVD, or the like. The thickness of the upper electrode film 114 is 100 nm to 300 nm, for example.

In implementing the present embodiment, there are no particular restrictions on the sequence in which the step of annealing the piezoelectric film 112 and the step of forming the upper electrode film 114 are carried out, and it is also possible to adopt the opposite sequence with respect to the present method of manufacture, in other words, a method where the piezoelectric film 112 is annealed after forming the upper electrode film 114. However, it is desirable to adopt the sequence in which the upper electrode film 114 is formed after annealing the piezoelectric film 112, since the piezoelectric characteristics of the piezoelectric film 112 can be enhanced further by the annealing process.

Next, the upper electrode film 114 is patterned by etching (FIG. 2F). More specifically, the upper electrode film 114 is patterned by dry etching (RIE) which uses a fluorine gas or chlorine gas. Instead of the steps of forming the solid upper electrode film 114 over the piezoelectric film 112 and then etching same, it is also possible to form pieces of upper electrode film 114 over the piezoelectric film 112 by means of a lift-off film deposition technique which uses a resist.

Next, the piezoelectric film 112 is patterned by etching (FIG. 2G). More specifically, similarly to the upper electrode film 114, the lower electrode film 114 is patterned by dry etching (RIE) which uses a fluorine gas or chlorine gas. In this case, it is desirable that etching is performed in such a manner that the piezoelectric film 112 is removed completely from the insulating layer 108, and thereby detachment of the piezoelectric film 112 can be prevented. Furthermore, although not shown in the drawings, a mode is also possible in which the upper electrode film 114 and the piezoelectric film 112 are etched simultaneously.

Next, an opening section 116, which is to form a pressure chamber 14, is formed by etching, or the like, in the supporting body (silicon substrate) 102, which constitutes the lower surface side of the SOI substrate 100 (FIG. 2H). Subsequently, a flow channel forming substrate 118 in which the nozzles 12 and the common flow channel 20, and the like, are formed is bonded to the lower surface side of the SOI substrate 100 (FIG. 2I).

Finally, one end of the external wire 38 is bonded to the upper electrode film 114 by means of a conductive adhesive, whereby it is possible to obtain the recording head 10 according to the present embodiment (FIG. 2J).

According to the present method of manufacture, after depositing the piezoelectric film 112 having the perovskite structure, the annealing process is carried out in the oxygen atmosphere at the prescribed heating temperature (the temperature equal to or lower than the film formation temperature of the piezoelectric film 112), and therefore it is possible to prevent detachment of the piezoelectric film 112 as well as being able to improve the piezoelectric characteristics. Furthermore, it is desirable that the annealing process is carried out in the oxygen atmosphere where the oxygen concentration is equal to or higher than 10 vol %, and hence the piezoelectric characteristics of the piezoelectric film 112 can be enhanced further.

There follows a discussion of the results of evaluation experiments into the change in piezoelectric characteristics, which were carried out by changing the heating temperature adopted during the annealing process (annealing temperature).

### Evaluation Experiment 1

In the evaluation experiment 1, after the piezoelectric film (PZT film) having the perovskite structure of Pb(Zr, Ti)O₃ had been formed by sputtering, and before forming the upper electrode film, the piezoelectric constant d31 of the piezoelectric film was measured after the annealing process for 30 minutes at the prescribed heating temperature (annealing temperature). Respective measurements were made for oxygen concentrations of 0, 3, 7 and 10 vol % in the atmosphere of the annealing process. The temperature during formation of the piezoelectric film (film formation temperature) was 550° C.

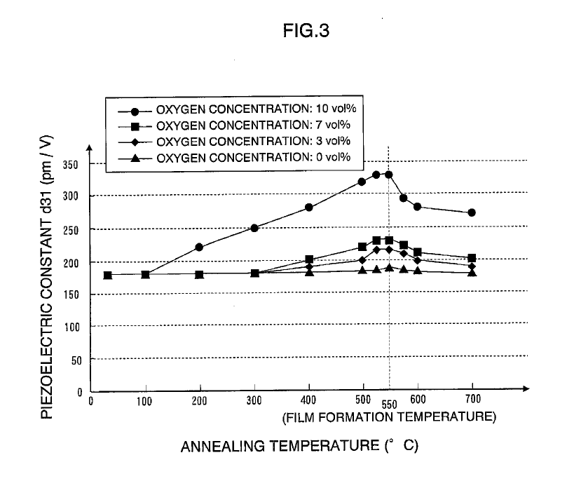

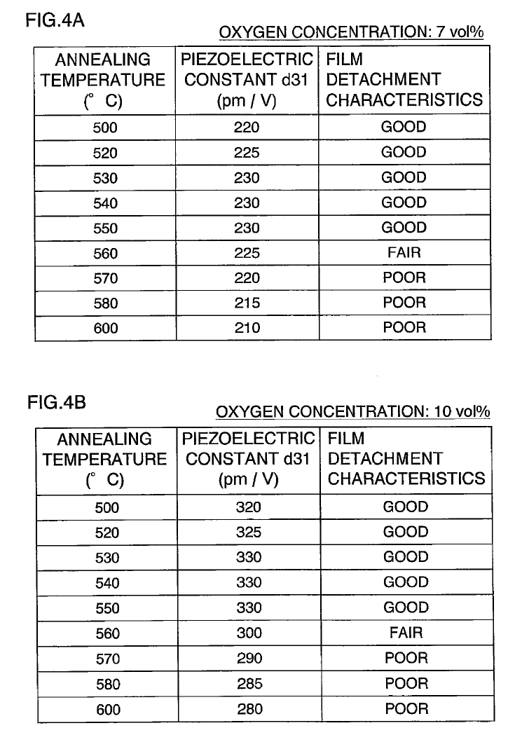

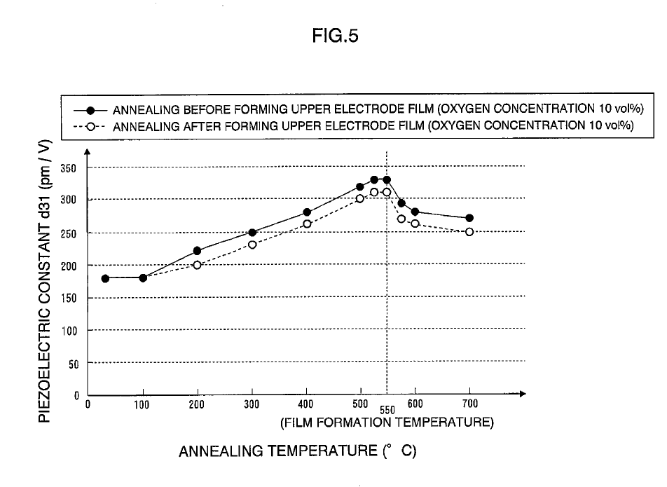

FIG. 3 is a graph showing the results of the evaluation experiment 1, and it plots the relationship between the annealing temperature and the piezoelectric constant d31. FIGS. 4A and 4B are tables showing the detailed data of the graphs shown in FIG. 3, and it represents the evaluation results relating to the piezoelectric constant d31 and the film detachment, at respective annealing temperatures. FIG. 4A relates to the cases where the oxygen concentration was 7 vol %, and FIG. 4B relates to the cases where the oxygen concentration was 10 vol %.

As shown in FIG. 3, it can be seen that if the heating temperature when carrying out the annealing process (the annealing temperature) was around the film formation temperature (550° C.), then the piezoelectric constant d31 was greatest, and hence a large effect in enhancing the piezoelectric characteristics by annealing was obtained. However, as shown in FIGS. 4A and 4B, if the annealing temperature was equal to 570° C. (over the film formation temperature by 20° C.) or higher, then detachment of the piezoelectric film 112 occurred (i.e., poor characteristics). On the other hand, if the annealing temperature was 560° C. (over the film formation temperature by 10° C.), then although very slight film detachment occurred, this was of a level which does not affect reliability (i.e., fair characteristics). Furthermore, if the annealing temperature was equal to or lower than 550° C. (the film formation temperature), then no film detachment occurred at all (i.e., good characteristics). Although not shown in the drawings, the results obtained when the oxygen concentration was 3 vol % were similar to those obtained where the oxygen concentration was 7 vol % or 10 vol %.

Moreover, in FIG. 3, if the oxygen concentration in the atmosphere in which the annealing process was carried out was 0 vol %, then the piezoelectric constant d31 was substantially uniform, regardless of the annealing temperature, and therefore virtually no effect in improving the piezoelectric characteristics by means of the annealing process was obtained.

On the other band, if the oxygen concentration in the atmosphere where the annealing process was carried out was 3, 7 or 10 vol %, then the piezoelectric constant d31 was greater than if the oxygen concentration was 0 vol %. Furthermore, it can be seen that the piezoelectric constant d31 became larger as the oxygen concentration became higher, and the piezoelectric characteristics were enhanced further, the higher the oxygen concentration in the atmosphere in which the annealing process was carried out. If the oxygen concentration was 10 vol %, then the piezoelectric constant d31 was raised significantly in comparison with a case where the oxygen concentration was equal to 7 vol % or lower. Consequently, it can be surmised that if the oxygen concentration is equal to or higher than 10 vol %, then the effect in improving the piezoelectric characteristics becomes extremely high. Hence, it is desirable that the oxygen concentration in the atmosphere where the annealing process is carried out is equal to or higher than 10 vol %, since this makes it possible to improve the piezoelectric characteristics yet further.

Desirably, the annealing temperature is equal to or higher than 100° C. This is because if the annealing temperature is lower than 100° C., then it is difficult to obtain an effect in enhancing the piezoelectric characteristics. If the oxygen concentration in the atmosphere where the annealing process is carried out is equal to or lower than 7 vol %, then the annealing temperature is desirably 300° C. or higher.

If a material of PZT with added Nb, La, or the like (e.g., (Pb, La)(Zr, Ti)O₃ or Pb(Zr, Nb)O₃—PbTiO₃) was used as the piezoelectric film having the perovskite structure, then it was possible to obtain results which were virtually the same as those described above.

The above-described results are summarized as follows: by carrying out the annealing process in the oxygen atmosphere at the prescribed heating temperature (equal to or lower than the film formation temperature of the piezoelectric film), it is possible to prevent detachment of the piezoelectric film, as well as being able to improve the piezoelectric characteristics. Furthermore, it is desirable that the annealing process is carried out in the oxygen atmosphere where the oxygen concentration is equal to or higher than 10 vol %, since this makes it possible to enhance the piezoelectric characteristics of the piezoelectric film yet further. Furthermore, desirably, the annealing temperature is equal to or higher than 100° C., since this makes it possible to obtain an effect in improving the piezoelectric characteristics by means of the annealing process. If the annealing process is carried out in the oxygen atmosphere having the oxygen concentration of 7 vol % or lower, then it is more desirable that the annealing temperature is equal to or higher than 300° C.

### Evaluation Experiment 2

In the evaluation experiment 2, the piezoelectric characteristics were evaluated by changing the sequence of the annealing process step and the step of forming the upper electrode film. More specifically, the piezoelectric constant d31 of the piezoelectric film was measured respectively in a case where the annealing process was carried out after depositing the piezoelectric film (PZT film) having the perovskite structure by a sputtering method and before forming the upper electrode film, and in a case where the annealing process was carried out after forming the upper electrode film. In both cases, the results relate to examples where the annealing process was carried out for 30 minutes in the atmosphere having the oxygen concentration of 10 vol %.

FIG. 5 shows the results of the evaluation experiment 2. As FIG. 5 reveals, compared to the case where the annealing process was carried out after forming the upper electrode film, when the annealing process was carried out before forming the upper electrode film, a higher piezoelectric constant d31 was obtained at the same annealing temperature. This is thought to be because it was possible to improve the crystallinity of the piezoelectric film, while preventing decline in the piezoelectric characteristics which are caused by the stress generated due to pyroelectric effects and the difference in the coefficient of linear expansion between the upper electrode film and the piezoelectric film.

From the above, it is desirable to carry out the annealing process before forming the upper electrode film, since this makes it possible to improve the piezoelectric characteristics yet further.

### Inkjet Recording Apparatus

Next an inkjet recording apparatus which is an embodiment of the image forming apparatus according to the present invention is described.

FIG. 6 is a diagram of the general composition showing an outline of the inkjet recording apparatus 200. As shown in FIG. 6, the inkjet recording apparatus 200 includes: a printing unit 212 having a plurality of recording heads 212K, 212C, 212M, and 212Y for ink colors of black (K), cyan (C), magenta (M), and yellow (Y), respectively; an ink storing and loading unit 214 for storing inks of K, C, M and Y to be supplied to the recording heads 212K, 212C, 212M, and 212Y; a paper supply unit 218 for supplying recording paper 216; a decurling unit 220 for removing curl in the recording paper 216; a suction belt conveyance unit 222 disposed facing the nozzle face (ink-droplet ejection face) of the printing unit 212, for conveying the recording paper 216 while keeping the recording paper 216 flat; a print determination unit 224 for reading the printed result produced by the printing unit 212; and a paper output unit 226 for outputting image-printed recording paper (printed matter) to the exterior. Each of the recording heads 212K, 212C, 212M and 212Y corresponds to the recording head 10 shown in FIG. 1.

In FIG. 6, a magazine for rolled paper (continuous paper) is shown as an example of the paper supply unit 218; however, more magazines with paper differences such as paper width and quality may be jointly provided. Moreover, papers may be supplied with cassettes that contain cut papers loaded in layers and that are used jointly or in lieu of the magazine for rolled paper.

In the case of a configuration in which roll paper is used, a cutter 228 is arranged as shown in FIG. 6, and the roll paper is cut to a desired size by the cutter 228. The cutter 228 has a stationary blade 228A, whose length is not less than the width of the conveyor pathway of the recording paper 216, and a round blade 228B, which moves along the stationary blade 228A. The stationary blade 228A is disposed on the reverse side of the printed surface of the recording paper 216, and the round blade 228B is disposed on the printed surface side across the conveyance path. When cut paper is used, the cutter 228 is not required.

In the case of a configuration in which a plurality of types of recording paper can be used, it is preferable that an information recording medium such as a bar code and a wireless tag containing information about the type of paper is attached to the magazine, and by reading the information contained in the information recording medium with a predetermined reading device, the type of paper to be used is automatically determined, and ink-droplet ejection is controlled so that the ink-droplets are ejected in an appropriate manner in accordance with the type of paper.

The recording paper 216 delivered from the paper supply unit 218 retains curl due to having been loaded in the magazine. In order to remove the curl, heat is applied to the recording paper 216 in the decurling unit 220 by a heating drum 230 in the direction opposite from the curl direction in the magazine. The heating temperature at this time is preferably controlled so that the recording paper 216 has a curl in which the surface on which the print is to be made is slightly round outward.

The decurled and cut recording paper 216 is delivered to the suction belt conveyance unit 222. The suction belt conveyance unit 222 has a configuration in which an endless belt 233 is set around rollers 231 and 232 so that the portion of the endless belt 233 facing at least the nozzle face of the printing unit 212 and the sensor face of the print determination unit 224 forms a plane.

The belt 233 has a width that is greater than the width of the recording paper 216, and a plurality of suction apertures (not shown) are formed on the belt surface. A suction chamber 234 is disposed in a position facing the sensor surface of the print determination unit 224 and the nozzle surface of the printing unit 212 on the interior side of the belt 233, which is set around the rollers 231 and 232, as shown in FIG. 6. The suction chamber 234 provides suction with a fan 235 to generate a negative pressure, and the recording paper 216 is held on the belt 233 by suction.

The belt 233 is driven in the clockwise direction in FIG. 6 by the motive force of a motor (not shown) being transmitted to at least one of the rollers 231 and 232, which the belt 233 is set around, and the recording paper 216 held on the belt 233 is conveyed from left to right in FIG. 6.

Since ink adheres to the belt 233 when a marginless print job or the like is performed, a belt-cleaning unit 236 is disposed in a predetermined position (a suitable position outside the printing area) on the exterior side of the belt 233. Although the details of the configuration of the belt-cleaning unit 236 are not shown, examples thereof include a configuration in which the belt 233 is nipped with cleaning rollers such as a brush roller and a water absorbent roller, an air blow configuration in which clean air is blown onto the belt 233, or a combination of these. In the case of the configuration in which the belt 233 is nipped with the cleaning rollers, it is preferable to make the line velocity of the cleaning rollers different than that of the belt 233 to improve the cleaning effect.

The inkjet recording apparatus 200 may have a roller nip conveyance mechanism, in which the recording paper 216 is pinched and conveyed with nip rollers, instead of the suction belt conveyance unit 222. However, there is a drawback in the roller nip conveyance mechanism that the print tends to be smeared when the printing area is conveyed by the roller nip action because the nip roller makes contact with the printed surface of the paper immediately after printing. Therefore, the suction belt conveyance in which nothing comes into contact with the image surface in the printing area is preferable.

A heating fan 240 is disposed on the upstream side of the printing unit 212 in the conveyance pathway formed by the suction belt conveyance unit 222. The heating fan 240 blows heated air onto the recording paper 216 to heat the recording paper 216 immediately before printing so that the ink deposited on the recording paper 216 dries more easily.

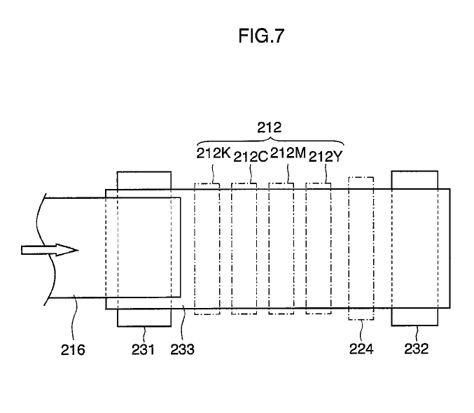

The printing unit 212 is a so-called “full line head” in which a line head having a length corresponding to the maximum paper width is arranged in a direction (main scanning direction) that is perpendicular to the paper conveyance direction (sub-scanning direction). The recording heads 212K, 212C, 212M and 212Y forming the printing unit 212 are constituted by line heads in which a plurality of ink ejection ports (nozzles) are arranged through a length exceeding at least one edge of the maximum size recording paper 216 intended for use with the inkjet recording apparatus 200 (see FIG. 7).

The recording heads 212K, 212C, 212M, and 212Y are arranged in the order of black (K), cyan (C), magenta (M), and yellow (Y) from the upstream side (from left in FIG. 6), along the conveyance direction of the recording paper 216 (paper conveyance direction). A color image can be formed on the recording paper 216 by ejecting the inks from the recording heads 212K, 212C, 212M, and 212Y, respectively, onto the recording paper 216 while conveying the recording paper 216.

The printing unit 212, in which the full-line heads covering the entire width of the paper are thus provided for the respective ink colors, can record an image over the entire surface of the recording paper 216 by performing the action of moving the recording paper 216 and the printing unit 212 relative to each other in the paper conveyance direction (sub-scanning direction) just once (in other words, by means of a single sub-scan). Higher-speed printing is thereby made possible and productivity can be improved in comparison with a shuttle type head configuration in which a recording head moves reciprocally in the direction (main scanning direction) that is perpendicular to the paper conveyance.

Although a configuration with four standard colors, K M C and Y, is described in the present embodiment, the combinations of the ink colors and the number of colors are not limited to these, and light and/or dark inks can be added as required. For example, a configuration is possible in which recording heads for ejecting light-colored inks such as light cyan and light magenta are added.

As shown in FIG. 6, the ink storing and loading unit 214 has ink tanks for storing the inks of the colors corresponding to the respective recording heads 212K, 212C, 212M, and 212Y, and the respective tanks are connected to the recording heads 212K, 212C, 212M, and 212Y by means of channels (not shown). The ink storing and loading unit 214 has a warning device (for example, a display device or an alarm sound generator and the like) for warning when the remaining amount of any ink is low, and has a mechanism for preventing loading errors among the colors.

The print determination unit 224 has an image sensor (line sensor and the like) for capturing an image of the ink-droplet deposition result of the printing unit 212, and functions as a device to check for ejection defects such as clogs of the nozzles in the printing unit 212 from the ink-droplet deposition results evaluated by the image sensor.

The print determination unit 224 of the present embodiment is configured with at least a line sensor having rows of photoelectric transducing elements with a width that is greater than the ink-droplet ejection width (image recording width) of the recording heads 212K, 212C, 212M, and 212Y. This line sensor has a color separation line CCD sensor including a red (R) sensor row composed of photoelectric transducing elements (pixels) arranged in a line provided with an R filter, a green (G) sensor row with a G filter, and a blue (B) sensor row with a B filter. Instead of a line sensor, it is possible to use an area sensor composed of photoelectric transducing elements which are arranged two-dimensionally.

The print determination unit 224 reads a test pattern image printed by the recording heads 212K, 212C, 212M, and 212Y for the respective colors, and the ejection of each head is determined. The ejection determination includes the presence of the ejection, measurement of the dot size, and measurement of the dot deposition position.

A post-drying unit 242 is disposed following the print determination unit 224. The post-drying unit 242 is a device to dry the printed image surface, and includes a heating fan, for example. It is preferable to avoid contact with the printed surface until the printed ink dries, and a device that blows heated air onto the printed surface is preferable.

In cases in which printing is performed with dye-based ink on porous paper, blocking the pores of the paper by the application of pressure prevents the ink from coming contact with ozone and other substance that cause dye molecules to break down, and has the effect of increasing the durability of the print.

A heating/pressurizing unit 244 is disposed following the post-drying unit 242. The heating/pressurizing unit 244 is a device to control the glossiness of the image surface, and the image surface is pressed with a pressure roller 245 having a predetermined uneven surface shape while the image surface is heated, and the uneven shape is transferred to the image surface.

The printed matter generated in this manner is outputted from the paper output unit 226. The target print (i.e., the result of printing the target image) and the test print are preferably outputted separately. In the inkjet recording apparatus 200, a sorting device (not shown) is provided for switching the outputting pathways in order to sort the printed matter Is with the target print and the printed matter with the test print, and to send them to paper output units 226A and 226B, respectively. When the target print and the test print are simultaneously formed in parallel on the same large sheet of paper, the test print portion is cut and separated by a cutter (second cutter) 248. The cutter 248 is disposed directly in front of the paper output unit 226, and is used for cutting the test print portion from the target print portion when a test print has been performed in the blank portion of the target print. The structure of the cutter 248 is the same as the first cutter 228 described above, and has a stationary blade 248A and a round blade 248B. Although not shown in FIG. 6, the paper output unit 226A for the target prints is provided with a sorter for collecting prints according to print orders.

FIG. 8 is a principal block diagram showing the control system of the inkjet recording apparatus 200. The inkjet recording apparatus 200 has a communication interface 270, a system controller 272, an image memory 274, a motor driver 276, a heater driver 278, a print controller 280, an image buffer memory 282, a head driver 284, and the like.

The communication interface 270 is an interface unit for receiving image data sent from a host computer 286. A serial interface such as USB (Universal Serial Bus), IEEE1394, Ethernet (trademark), wireless network, or a parallel interface such as a Centronics interface may be used as the communication interface 270. A buffer memory (not shown) may be mounted in this portion in order to increase the communication speed. The image data sent from the host computer 286 is received by the inkjet recording apparatus 200 through the communication interface 270, and is temporarily stored in the image memory 274.

The image memory 274 is a storage device for temporarily storing images inputted through the communication interface 270, and data is written and read to and from the image memory 274 through the system controller 272. The image memory 274 is not limited to a memory composed of semiconductor elements, and a hard disk drive or another magnetic medium may be used.

The system controller 272 is a control unit for controlling the various sections, such as the communications interface 270, the image memory 274, the motor driver 276, the heater driver 278, and the like. The system controller 272 is constituted by a central processing unit (CPU) and peripheral circuits thereof, and the like, and in addition to controlling communications with the host computer 286 and controlling reading and writing from and to the image memory 274, or the like, it also generates a control signal for controlling the motor 288 of the conveyance system and the heater 289.

The motor driver (drive circuit) 276 drives the motor 288 in accordance with commands from the system controller 272. The heater driver (drive circuit) 278 drives the heater 289 of the post-drying unit 242 or the like in accordance with commands from the system controller 272.

The print controller 280 has a signal processing function for performing various tasks, compensations, and other types of processing for generating print control signals from the image data stored in the image memory 274 in accordance with commands from the system controller 272 so as to supply the generated print control signal (dot data) to the head driver 284. Prescribed signal processing is carried out in the print controller 280, and the ejection amount and the ejection timing of the ink from the respective recording heads 212K, 212C, 212M, and 212Y are controlled via the head driver 284, on the basis of the print data. By this means, prescribed dot size and dot positions can be achieved.

The print controller 280 is provided with the image buffer memory 282; and image data, parameters, and other data are temporarily stored in the image buffer memory 282 when image data is processed in the print controller 280. The aspect shown in FIG. 8 is one in which the image buffer memory 282 accompanies the print controller 280; however, the image memory 274 may also serve as the image buffer memory 282. Also possible is an aspect in which the print controller 280 and the system controller 272 are integrated to form a single processor.

The head driver 284 generates drive signals for driving the piezoelectric elements 36 (see FIG. 1) of the recording heads 212K, 212C, 212M, 212Y of the respective colors, on the basis of the dot data supplied from the print controller 280, and supplies the generated drive signals to the piezoelectric elements 36. It is also possible to include a feedback control system in the head driver 284 in order to maintain uniform drive conditions of the recording heads 212K, 212C, 212M and 212Y.

The print determination unit 224 is a block that includes the line sensor as described above with reference to FIG. 6, reads the image printed on the recording paper 216, determines the print conditions (presence of the ejection, variation in the dot formation, and the like) by performing desired signal processing, or the like, and provides the determination results of the print conditions to the print controller 280.

According to requirements, the print controller 280 makes various corrections with respect to the recording head 212K, 212C, 212M and 212Y on the basis of information obtained from the print determination unit 224.

The method of manufacturing the piezoelectric actuator, and the liquid ejection head and the image forming apparatus according to the present invention have been described in detail above, but the present invention is not limited to the aforementioned examples, and it is of course possible for improvements or modifications of various kinds to be implemented, within a range which does not deviate from the essence of the present invention.

It should be understood, however, that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A method of manufacturing a piezoelectric actuator comprising an upper electrode film, a lower electrode film and a piezoelectric film arranged between the upper electrode film and the lower electrode film, the piezoelectric film being made of a material having a perovskite crystal structure as represented by a general formula ABO₃, where A includes at least one of Pb and Ba, and B includes at least one of Zr and Ti, the method comprising the steps of:
forming the piezoelectric film on the lower electrode film; and
then annealing the piezoelectric film in an oxygen atmosphere at a temperature not higher than a temperature having been applied to the piezoelectric film during the step of forming.

2. The method as defined in claim 1, wherein the piezoelectric film is formed by a sputtering method.

3. The method as defined in claim 1, wherein an oxygen concentration of the oxygen atmosphere is not lower than 10 vol %.

4. The method as defined in claim 1, further comprising the step of forming the upper electrode film on the piezoelectric film before the step of annealing.

5. A liquid ejection head, comprising a piezoelectric actuator manufactured by the method as defined in claim 1.

6. An image forming apparatus, comprising the liquid ejection head as defined in claim 5.
